(19) United States
(12) Patent Application Publication
(10) Pub. No.: US 2017/0187183 A1
(43) Pub. Date: Jun. 29, 2017

(54) CHIP AND ELECTRONIC DEVICE

(71) Applicant: Shenzhen China Star Optoelectronics Technology Co., Ltd., Shenzhen, Guangdong (CN)

(72) Inventors: Xianming ZHANG, Shenzhen, Guangdong (CN); Yu-Yeh CHEN, Shenzhen, Guangdong (CN); Ming-wei CHEN, Shenzhen, Guangdong (CN); Dan CAO, Shenzhen, Guangdong (CN)

(73) Assignee: Shenzhen China Star Optoelectronics Technology Co., Ltd., Shenzhen, Guangdong (CN)

(21) Appl. No.: 14/904,781

(22) PCT Filed: Dec. 8, 2015
(86) PCT No.: PCT/CN2015/096644

§ 371 Date: Jan. 13, 2016

(30) Foreign Application Priority Data
Aug. 7, 2015 (CN) 201510484331.1

(51) Int. Cl. H02H 9/04; H01L 27/02

(52) U.S. Cl. CPC H02H 9/046; H01L 27/0255

(57) ABSTRACT

The present invention provides a chip and an electronic device. The chip comprises at least one pin, and the chip comprises at least one ESD (Electrostatic Discharge) protection circuit inside, and the ESD protection circuit is employed to reduce or eliminate a damage of electrostatic to other elements or circuit inside the chip, and the ESD protection circuit is located corresponding to a pin, and the ESD protection circuit is electrically coupled to the pin. The electronic device comprises the aforesaid chip.

### CROSS REFERENCE

This application claims the priority of Chinese Patent Application No. 2015010484331.1, entitled “Chip and electronic device”, filed on Aug. 7, 2015, the disclosure of which is incorporated herein by reference in its entirety.

### FIELD OF THE INVENTION

The present invention relates to an electronic technology field, and more particularly to a chip and an electronic device.

### BACKGROUND OF THE INVENTION

The electrostatic is a kind of objective existence of natural phenomena, there are many to produce it, such as contact, friction, electric induction, etc. The characteristic of the electrostatic is long time accumulation, high voltage, low power, small current and short time action. With the factors of the body's own actions or contact with other objects, separation, friction or induction, it can produce the electrostatic of several thousand volts or even tens of thousands of volts. Triboelectrification and human body electrostatic are two great harms in the electronics industry, which often cause the operation instability of the chip in the electronic device, or even damage. Thus, it results in poor quality of electronic device.

### SUMMARY OF THE INVENTION

The present invention provides a chip, and the chip comprises at least one pin, and the chip comprises at least one ESD (Electrostatic Discharge) protection circuit inside, and the ESD protection circuit is employed to reduce or eliminate a damage of electrostatic to other elements or circuit inside the chip, and the ESD protection circuit is located corresponding to a pin, and the ESD protection circuit is electrically coupled to the pin.

The ESD protection circuit comprises a first single way conduction unit and a second single way conduction unit, and the first single way conduction unit comprises a first end and a second end, and as a voltage of the first end is larger than a voltage-a preset voltage of the second end, and the first single way conduction unit is conducted, and the second single way conduction unit comprises a third end and a fourth end, and as a voltage of the third end is larger than a voltage-a preset voltage of the fourth end, and the fourth single way conduction unit is conducted, and the first end is grounded, and the second end is coupled to the third end, and the second end is electrically coupled to the pin corresponded with the ESD protection circuit, and the second end is electrically coupled to the other elements or the circuit inside the chip, and the fourth end is applied with a preset positive voltage.

The first single way conduction unit and the second single way conduction unit are diodes, and the first end and the third end are positive electrodes of the diodes, and the second end and the fourth end are negative electrodes of the diodes.

The pin electrically coupled to the ESD protection circuit is a pin of receiving an external signal.

Other pins of the chip except the pin of receiving the external signal are not electrically coupled to the ESD protection circuit.

The present invention further provides an electronic device, wherein the electronic device comprises a chip, and the chip comprises at least one pin, and the chip comprises at least one ESD (Electrostatic Discharge) protection circuit inside, and the ESD protection circuit is employed to reduce or eliminate a damage of electrostatic to other elements or circuit inside the chip, and the ESD protection circuit is located corresponding to a pin, and the ESD protection circuit is electrically coupled to the pin.

The ESD protection circuit comprises a first single way conduction unit and a second single way conduction unit, and the first single way conduction unit comprises a first end and a second end, and as a voltage of the first end is larger than a voltage-a preset voltage of the second end, and the first single way conduction unit is conducted, and the second single way conduction unit comprises a third end and a fourth end, and as a voltage of the third end is larger than a voltage-a preset voltage of the fourth end, and the fourth single way conduction unit is conducted, and the first end is grounded, and the second end is coupled to the third end, and the second end is electrically coupled to the pin corresponded with the ESD protection circuit, and the second end is electrically coupled to the other elements or the circuit inside the chip, and the fourth end is applied with a preset positive voltage.

The first single way conduction unit and the second single way conduction unit are diodes, and the first end and the third end are positive electrodes of the diodes, and the second end and the fourth end are negative electrodes of the diodes.

The pin electrically coupled to the ESD protection circuit is a pin of receiving an external signal.

Other pins of the chip except the pin of receiving the external signal are not electrically coupled to the ESD protection circuit.

Compared with prior art, the chip of the present invention and the chip in the electronic device having the chip comprises at least one ESD protection circuit, and the ESD protection circuit can reduce or eliminate the damage of electrostatic to other elements or circuit inside the chip, and thus to protect the stability when the chip is functioning. Furthermore, the ESD protection circuit of the chip according to the present invention is located inside the chip, and setting the ESD protection circuit outside the chip is not required. Compared with the condition that the ESD protection circuit is set outside the chip, the ESD protection circuit of the present invention is located inside the chip, and thus, the function of the chip is further integrated to avoid the trouble of being externally coupled to the ESD protection circuit when using.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a circuit structure diagram of a chip according to the preferred embodiment of the present invention.

FIG. 2 is a circuit diagram of an ESD protection circuit in a chip according to the preferred embodiment of the present invention.

FIG. 3 is a circuit structure diagram of an electronic device according to the preferred embodiment of the present invention.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

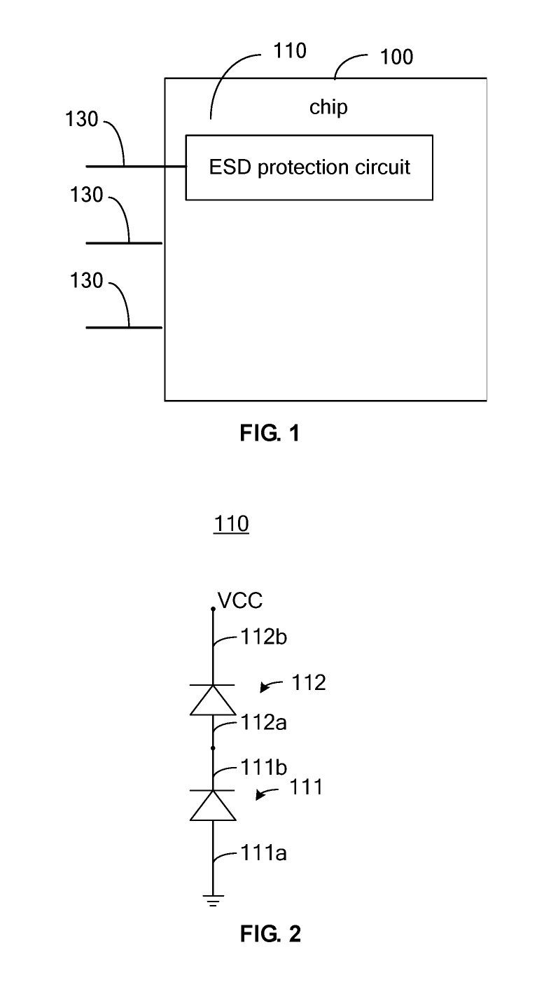

Please refer to FIG. 1 and FIG. 2, together. FIG. 1 is a circuit structure diagram of a chip according to the preferred embodiment of the present invention. FIG. 2 is a circuit diagram of an ESD protection circuit in a chip according to the preferred embodiment of the present invention. The chip 100 can be located in the electronic device. The electronic device comprises the smart phone, the mobile internet device (MID), the electronic book, the Play Station Portable (PSP) or Personal Digital Assistant (PDA) but not limited thereto. The chip 100 comprises at least one pin 130, and the chip 100 comprises at least one ESD (Electrostatic Discharge) protection circuit 110 inside, and the ESD protection circuit 110 is employed to reduce or eliminate a damage of electrostatic to other elements or circuit inside the chip 100, and the ESD protection circuit 110 is located corresponding to a pin 130, and the ESD protection circuit 110 is electrically coupled to the pin 130.

The ESD protection circuit 110 comprises a first single way conduction unit 111 and a second single way conduction unit 112. The first single way conduction unit 111 comprises a first end 111a and a second end 111b, and as a voltage of the first end 111a is larger than a voltage-a preset voltage of the second end 111b, and the first single way conduction unit 111 is conducted. The second single way conduction unit 112 comprises a third end 112a and a fourth end 112b, and as a voltage of the third end 112a is larger than a voltage-a preset voltage of the fourth end 112b, and the fourth single way conduction unit 112 is conducted. The first end 111a is grounded, and the second end 111b is coupled to the third end 112a, and the second end 111b is electrically coupled to the pin 130 corresponded with the ESD protection circuit 110, and the second end 111b is electrically coupled to the other elements or the circuit inside the chip 100. The fourth end 112b is applied with a preset positive voltage VCC.

In one embodiment, the first single way conduction unit 111 is a diode. Correspondingly, the first end 111a is the positive electrode of the diode, and the second end 111b is the negative electrode of the diode. When the voltage applied to the positive electrode of the diode is larger than the voltage-a preset voltage of the negative electrode, the diode is conducted. Otherwise, the diode is cutoff.

In one embodiment, the second single way conduction unit 112 is a diode. Correspondingly, the third end 112a is the positive electrode of the diode, and the fourth end 112b is the negative electrode of the diode. When the voltage applied to the positive electrode of the diode is larger than the voltage-a preset voltage of the negative electrode, the diode is conducted. Otherwise, the diode is cutoff.

Preferably, the pin electrically coupled to the ESD protection circuit 110 is a pin of receiving an external signal. Other pins of the chip 130 except the pin of receiving the external signal are not electrically coupled to the ESD protection circuit 110. Thus, the chip 100 possesses the ESD ability and no more loading is not brought to the chip 100 to prevent the cost increase of the chip 100.

Preferably, the voltage of the signal applied to the pin 130 coupled to the ESD protection circuit 110 is larger than or equal to zero voltage, and smaller than or equal to the positive voltage VCC. Then, the signal applied to the pin 130 coupled to the ESD protection circuit 110 will not breakdown the first single way conduction unit 111 and the second single way conduction unit 112 or conduct the first single way conduction unit 111 and the second single way conduction unit 112 in the ESD protection circuit 110. Meanwhile, the ESD protection circuit 110 will not influence the signal applied to the pin coupled to the ESD protection circuit 110. Here, the signal applied to the pin 130 comprises: the signals inputted to the other elements or the circuit inside the chip 100 through the pin 130, and the signal outputted to the exterior of the chip 100 by the chip 100 through the pin 130.

Compared with prior art, the chip 100 of the present invention comprises at least one ESD protection circuit 110, and the ESD protection circuit 110 can reduce or eliminate the damage of electrostatic to other elements or circuit inside the chip 100, and thus to protect the stability when the chip is functioning. Furthermore, the ESD protection circuit 110 of the chip 100 according to the present invention is located inside the chip 100, and setting the ESD protection circuit 110 outside the chip 100 is not required. Compared with the condition that the ESD protection circuit 110 is set outside the chip 100, the ESD protection circuit 110 of the present invention is located inside the chip 100, and thus, the function of the chip 100 is further integrated to avoid the trouble of being externally coupled to the ESD protection circuit when using.

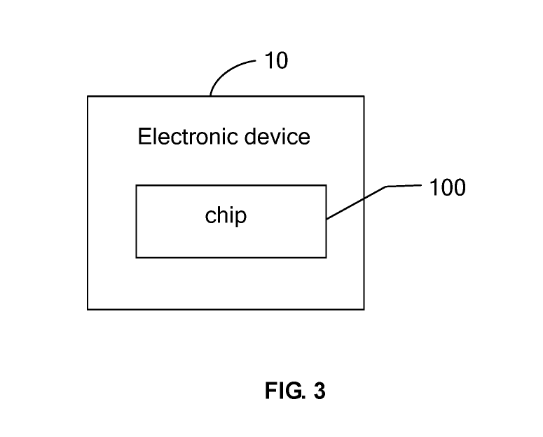

With combination of FIG. 1 and FIG. 2, the electronic device according to the present invention is introduced. Please refer to FIG. 3. FIG. 3 is a circuit structure diagram of an electronic device according to the preferred embodiment of the present invention. The electronic device comprises the smart phone, the mobile internet device, the electronic book, the Play Station Portable or Personal Digital Assistant but not limited thereto. The electronic device 10 comprises a chip 100, and the chip 100 comprises at least one pin 130, and the chip 100 comprises at least one ESD protection circuit 110 inside, and the ESD protection circuit 110 is employed to reduce or eliminate a damage of electrostatic to other elements or circuit inside the chip 100, and the ESD protection circuit 110 is located corresponding to a pin 130, and the ESD protection circuit 110 is electrically coupled to the pin 130.

The ESD protection circuit 110 comprises a first single way conduction unit 111 and a second single way conduction unit 112. The first single way conduction unit 111 comprises a first end 111a and a second end 111b, and as a voltage of the first end 111a is larger than a voltage-a preset voltage of the second end 111b, and the first single way conduction unit 111 is conducted. The second single way conduction unit 112 comprises a third end 112a and a fourth end 112b, and as a voltage of the third end 112a is larger than a voltage-a preset voltage of the fourth end 112b, and the fourth single way conduction unit 112 is conducted. The first end 111a is grounded, and the second end 111b is coupled to the third end 112a, and the second end 111b is electrically coupled to the pin 130 corresponded with the ESD protection circuit 110, and the second end 111b is electrically coupled to the other elements or the circuit inside the chip 100. The fourth end 112b is applied with a preset positive voltage VCC.

In one embodiment, the first single way conduction unit 111 is a diode. Correspondingly, the first end 111a is the positive electrode of the diode, and the second end 111b is the negative electrode of the diode. When the voltage applied to the positive electrode of the diode is larger than the voltage-a preset voltage of the negative electrode, the diode is conducted. Otherwise, the diode is cutoff.

In one embodiment, the second single way conduction unit 112 is a diode. Correspondingly, the third end 112a is the positive electrode of the diode, and the fourth end 112b is the negative electrode of the diode. When the voltage applied to the positive electrode of the diode is larger than the voltage-a preset voltage of the negative electrode, the diode is conducted. Otherwise, the diode is cutoff.

Preferably, the pin electrically coupled to the ESD protection circuit 110 is a pin of receiving an external signal. Other pins of the chip 130 except the pin of receiving the external signal are not electrically coupled to the ESD protection circuit 110. Thus, the chip 100 possesses the ESD ability and no more loading is not brought to the chip 100 to prevent the cost increase of the chip 100.

Preferably, the voltage of the signal applied to the pin 130 coupled to the ESD protection circuit 110 is larger than or equal to zero voltage, and smaller than or equal to the positive voltage VCC. Then, the signal applied to the pin 130 coupled to the ESD protection circuit 110 will not breakdown the first single way conduction unit 111 and the second single way conduction unit 112 or conduct the first single way conduction unit 111 and the second single way conduction unit 112 in the ESD protection circuit 110. Meanwhile, the ESD protection circuit 110 will not influence the signal applied to the pin coupled to the ESD protection circuit 110. Here, the signal applied to the pin 130 comprises: the signals inputted to the other elements or the circuit inside the chip 100 through the pin 130, and the signal outputted to the exterior of the chip 100 by the chip 100 through the pin 130.

Compared with prior art, the chip 100 in the electronic device 10 of the present invention comprises at least one ESD protection circuit 110, and the ESD protection circuit 110 can reduce or eliminate the damage of electrostatic to other elements or circuit inside the chip 100, and thus to protect the stability when the chip 100 is functioning and to raise the quality of the electronic device 10. Furthermore, the ESD protection circuit 110 of the chip 100 according to the present invention is located inside the chip 100, and setting the ESD protection circuit 110 outside the chip 100 is not required. Compared with the condition that the ESD protection circuit 110 is set outside the chip 100, the ESD protection circuit 110 of the present invention is located inside the chip 100, and thus, the function of the chip 100 is further integrated to avoid the trouble of being externally coupled to the ESD protection circuit when using.

Above are embodiments of the present invention, which does not limit the scope of the present invention. Any modifications, equivalent replacements or improvements within the spirit and principles of the embodiment described above should be covered by the protected scope of the invention.

What is claimed is:

1. A chip, wherein the chip comprises at least one pin, and the chip comprises at least one ESD (Electrostatic Discharge) protection circuit inside, and the ESD protection circuit is employed to reduce or eliminate a damage of electrostatic to other elements or circuit inside the chip, and the ESD protection circuit is located corresponding to a pin, and the ESD protection circuit is electrically coupled to the pin.

2. The chip according to claim 1, wherein the ESD protection circuit comprises a first single way conduction unit and a second single way conduction unit, and the first single way conduction unit comprises a first end and a second end, and as a voltage of the first end is larger than a voltage-a preset voltage of the second end, and the first single way conduction unit is conducted, and the second single way conduction unit comprises a third end and a fourth end, and as a voltage of the third end is larger than a voltage-a preset voltage of the fourth end, and the fourth single way conduction unit is conducted, and the first end is grounded, and the second end is coupled to the third end, and the second end is electrically coupled to the pin corresponded with the ESD protection circuit, and the second end is electrically coupled to the other elements or the circuit inside the chip, and the fourth end is applied with a preset positive voltage.

3. The chip according to claim 2, wherein the first single way conduction unit and the second single way conduction unit are diodes, and the first end and the third end are positive electrodes of the diodes, and the second end and the fourth end are negative electrodes of the diodes.

4. The chip according to claim 1, wherein the pin electrically coupled to the ESD protection circuit is a pin of receiving an external signal.

5. The chip according to claim 4, wherein other pins of the chip except the pin of receiving the external signal are not electrically coupled to the ESD protection circuit.

6. An electronic device, wherein the electronic device comprises a chip, and the chip comprises at least one pin, and the chip comprises at least one ESD (Electrostatic Discharge) protection circuit inside, and the ESD protection circuit is employed to reduce or eliminate a damage of electrostatic to other elements or circuit inside the chip, and the ESD protection circuit is located corresponding to a pin, and the ESD protection circuit is electrically coupled to the pin.

7. The electronic device according to claim 6, wherein the ESD protection circuit comprises a first single way conduction unit and a second single way conduction unit, and the first single way conduction unit comprises a first end and a second end, and as a voltage of the first end is larger than a voltage-a preset voltage of the second end, and the first single way conduction unit is conducted, and the second single way conduction unit comprises a third end and a fourth end, and as a voltage of the third end is larger than a voltage-a preset voltage of the fourth end, and the fourth single way conduction unit is conducted, and the first end is grounded, and the second end is coupled to the third end, and the second end is electrically coupled to the pin corresponded with the ESD protection circuit, and the second end is electrically coupled to the other elements or the circuit inside the chip, and the fourth end is applied with a preset positive voltage.

8. The electronic device according to claim 7, wherein the first single way conduction unit and the second single way conduction unit are diodes, and the first end and the third end are positive electrodes of the diodes, and the second end and the fourth end are negative electrodes of the diodes.

9. The electronic device according to claim 6, wherein the pin electrically coupled to the ESD protection circuit is a pin of receiving an external signal.

10. The electronic device according to claim 9, wherein other pins of the chip except the pin of receiving the external signal are not electrically coupled to the ESD protection circuit.
